(19) United States
(12) Patent Application Publication
(10) Pub. No.: US 2024/0193334 A1
(43) Pub. Date: Jun. 13, 2024

(54) MACRO MODEL OF A SEMICONDUCTOR INTEGRATED CIRCUIT DEVICE, CIRCUIT DESIGN SIMULATION PROGRAM, AND CIRCUIT DESIGN SIMULATOR

(71) Applicant: ROHM CO., LTD., Kyoto (JP)

(72) Inventors: Kyoji MARUMOTO, Kyoto (JP); Takuya KATAYAMA, Kyoto (JP)

(21) Appl. No.: 18/584,264

(22) Filed: Feb. 22, 2024

Related U.S. Application Data
(63) Continuation of application No. PCT/JP2022/033689, filed on Sep. 8, 2022.

(30) Foreign Application Priority Data
Sep. 27, 2021 (JP) 2021-156469

(51) Int. Cl. G06F 30/3308; G06F 1/20

(52) U.S. Cl. CPC G06F 30/3308; G06F 1/206

(57) ABSTRACT

According to one aspect of what is disclosed herein, a macro model of a semiconductor integrated circuit device is for use on a circuit design simulator and includes: an input node configured to accept input of a second temperature condition which is set specifically and separately from a first temperature condition which is set for the entire system of the circuit design simulator; functional blocks configured to approximately or equivalently represent characteristics of the semiconductor integrated circuit device on the circuit design simulator; and a characteristics setting block configured to set internal parameters of the functional blocks so as to reflect the second temperature condition when the input node is fed with the second temperature condition.

### CROSS-REFERENCE TO RELATED APPLICATIONS

This nonprovisional application is a continuation application of International Patent Application No. PCT/JP2022/033689 filed on Sep. 8, 2022, which claims priority Japanese Patent Application No. 2021-156469 filed on Sep. 27, 2021, the entire contents of which are hereby incorporated by reference.

### TECHNICAL FIELD

The invention disclosed herein relates to a macro model of a semiconductor integrated circuit device, and to a circuit design simulation program and a circuit design simulator that employ such a macro model.

### BACKGROUND ART

Conventionally, as a tool for assisting the designing of a semiconductor integrated circuit device, a wide use is made of circuit design simulation programs (for example, SPICE [simulation program with integrated circuit emphasis] circuit design simulation programs). A circuit design simulation program is a software program that makes a computer executing it function as a circuit design simulator. On a circuit design simulator, it is possible to create an analog circuit by combining various simulation models (passive device models such as a resistor and a capacitor, active device models such as a transistor and a diode, and macro models such as an operational amplifier) with a voltage source, a current source, a wiring, and the like to simulate the response of the circuit.

An example of known technology related to what has just been mentioned is seen in Patent Document 1 identified below.

### CITATION LIST

### Patent Literature

Patent Document 1: Japanese unexamined patent application publication No. 2012-216187

### BRIEF DESCRIPTION OF DRAWINGS

FIG. 1 is a diagram showing an actual circuit example of an operational amplifier.

FIG. 2 is a diagram showing a comparative example of a macro model.

FIG. 3 is a diagram showing the characteristics of the operational amplifier.

FIG. 4 is a diagram showing a macro model according to a first embodiment.

FIG. 5 is a diagram showing a macro model according to a second embodiment.

FIG. 6 is a diagram showing an example of application of a temperature profile on a circuit board.

FIG. 7 is a diagram showing one configuration example of a circuit design simulator.

FIG. 8 is a diagram showing one configuration example of a circuit design simulation program.

### DESCRIPTION OF EMBODIMENTS

### <Operational Amplifier>

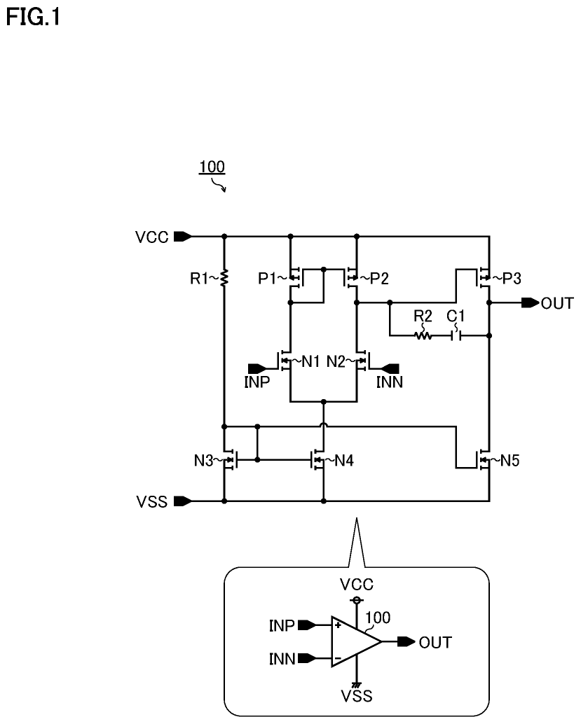

FIG. 1 is a diagram showing an actual circuit example of an operational amplifier. The operational amplifier 100 of this configuration example includes N-channel MOS [metal-oxide-semiconductor] field-effect transistors N1 to N5, P-channel MOS field-effect transistors P1 to P3, resistors R1 to R2, and a capacitor C1.

One terminal of the resistor R1 and the sources of the transistors P1, P2, and P3 are all connected to the supply voltage node (that is, an application terminal for a supply voltage VCC) of the operational amplifier 100. The second terminal of the resistor R1 is connected to the drain of the transistor N3. The gates of the transistors P1 and P2 are both connected to the drain of the transistor P1. The drain of the transistor P2, the gate of the transistor P3, and the first terminal of the resistor R2 are all connected to the drain of the transistor N2. The second terminal of the resistor R2 is connected to the first terminal of the capacitor C1. The drains of the transistors P3 and N5 and the second terminal of the capacitor C1 are all connected to the output node (that is, an output terminal for an output signal OUT) of the operational amplifier 100.

The gate of the transistor N1 is connected to the non-inverting input node (that is, an input terminal for a first input signal INP) of the operational amplifier 100. The gate of the transistor N2 is connected to the non-inverting input node (that is, an input terminal for a second input signal INN) of the operational amplifier 100. The sources of the transistors N1 and N2 are both connected to the drain of the transistor N4. The gates of the transistors N3, N4, and N5 are all connected to the drain of the transistor N3. The sources of the transistors N3, N4, and N5 are all connected to the reference voltage node (that is, an application terminal for a reference voltage VSS) of the operational amplifier 100.

The operational amplifier 100 of this configuration example amplifies the difference between the first and second input signals INP and INN at a gain a to generate an output signal OUT (=α×(INP−INN)).

Incidentally, with respect to semiconductor integrated circuit devices (LSI products in general), to provide a highly accurate simulation model that covers all actual operation conditions, it is necessary to represent all the circuit elements (transistors, resistors, capacitors, etc.) constituting a semiconductor integrated circuit device with element models and make a model of (hereinafter, model) an actual analog circuit itself.

However, by such a method, even simulating a small-scale semiconductor integrated circuit device takes a long time for computation by a circuit design simulator (such as a computer). In particular, simulating a large-scale system such as a PCB [printed circuit board] incorporating a semiconductor integrated circuit device takes too much time and may lead to slow progress of system designing.

In this way, it is not realistic to model an actual analog circuit itself to enhance the accuracy of simulation of a semiconductor integrated circuit device. Thus, generally used is a method of representing an actual analog circuit with a simple or equivalent circuit and modeling it.

### Macro Model (Comparative Example)

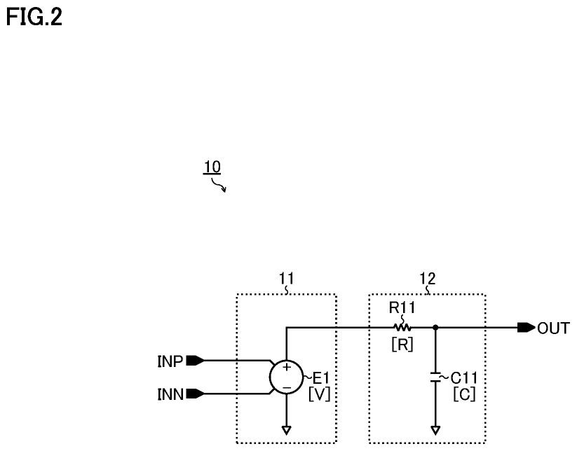

FIG. 2 is a diagram showing a comparative example (that is, a common configuration example to be compared with an embodiment, described later) of a macro model that simulates the operational amplifier 100. The macro model 10 of this comparative example includes a power supply block 11 and a filter block 12 as a plurality of functional blocks configured to approximately or equivalently represent the characteristics of the operational amplifier 100 on the circuit design simulator.

The power supply block 11 includes a direct-current power source E1 that receives the input of the first and second input signals INP and INN. An output voltage value V of the direct-current power source E1 is variable according to the difference between the first and second input signals INP and INN and corresponds to an internal parameter for representing the DC gain of the operational amplifier 100.

The filter block 12 is a one-stage RC filter that smooths the output voltage of the direct-current power source E1 to generate the output signal OUT and includes a resistor R11 and a capacitor C11. The resistance value R of the resistor R11 and the capacitance value C of the capacitor C11 each correspond to an internal parameter for representing the band width of the operational amplifier 100.

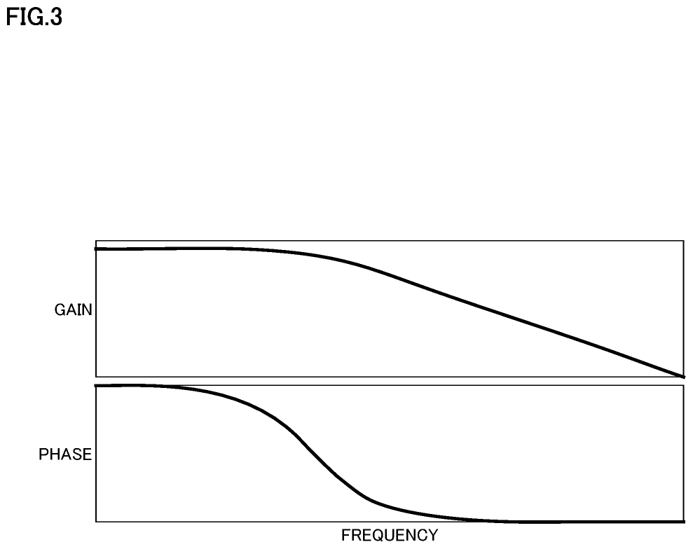

FIG. 3 is a Bode plot (top: gain plot, bottom: phase plot) showing the characteristics of the operational amplifier 100. In the gain and phase plots, the horizontal axes represents frequency. On the other hand, in the gain and phase plots, the vertical axes represents gain and phase, respectively, versus frequency.

When the macro model 10 of the operational amplifier 100 is created, various internal parameters (the output voltage value V, the resistance value R, and the capacitance value C) are adjusted so as to produce characteristics as shown in FIG. 3.

By using such a macro model 10, it is possible to reduce the computing load on the circuit design simulator, and to obtain a simulation results in a shorter time.

### <Discussion on Temperature Condition>

Incidentally, a conventional macro model of a semiconductor integrated circuit device has a function of representing the characteristics of the semiconductor integrated circuit device approximately or equivalently on a circuit design simulator so as to reflect a temperature condition (such as ambient temperature) set for the entire system of the circuit design simulator.

However, on the circuit design simulator, it is only possible to set one temperature condition (for example, 25° C.) for each simulation run. For example, for simulating the characteristics of a semiconductor integrated circuit device under a plurality of temperature conditions (e.g., −60° ° C., −40° C., 25° C., 125° C., and 150° C.), it is necessary to perform the same simulation repeatedly while changing from one temperature condition for the entire system to another.

For another example, even if a plurality of semiconductor integrated circuit devices implemented at different positions on a circuit board are simulated as separate macro models, the circuit design simulator can only set a uniform temperature condition to all of them. Thus, it is difficult to perform simulations reflecting the temperature profile on the circuit board.

Here, some conventional device models (active or passive device models) have a function of calculating the internal temperature Tj due to self-heating and reflecting it in their behavior (that is, what is called thermal models). However, using such thermal models for simulating semiconductor integrated circuit devices leads to an increase in the load and the processing time of the circuit design simulator.

In view of the above discussion, presented below is an embodiment of the macro model 10 that allows free setting of an temperature condition.

### A Macro Model (First Embodiment)

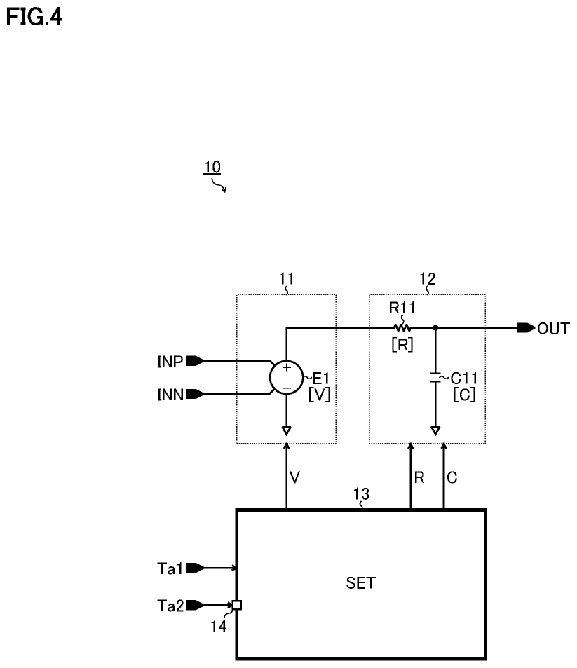

FIG. 4 is a diagram showing a macro model according to a first embodiment simulating the operational amplifier 100. The macro model 10 of this embodiment is based on the comparative example (FIG. 2) described previously and further includes a characteristics setting block 13 and an input node 14.

The input node 14 is a node for accepting input of an ambient temperature Ta2 (corresponding to a second temperature condition), which is set specifically for the macro model 10, separately from an ambient temperature Ta1 (corresponding to a first temperature condition), which is set for the entire system of the circuit design simulator.

The characteristics setting block 13 accepts input of the ambient temperature Ta1 set for the entire system of the circuit design simulator and in addition accepts input of the ambient temperature Ta2 set specifically for the macro model 10 via the input node 14.

The characteristics setting block 13 sets at least one internal parameter among a plurality of internal parameters set in each of the power supply block 11 and the filter block 12 such that the characteristics of the operational amplifier 100 on the circuit design simulator reflect the ambient temperature Ta1 or Ta2. Examples of the plurality of internal parameters include, for example, the output voltage value V with respect to the power supply block 11 and the resistance value R and the capacitance value C with respect to the filter block 12. Of these internal parameters, any one or two can be set as variable values (that is, as the targets of setting by the characteristics setting block 13), or all three of them can be set as variable values.

The characteristics setting block 13 may accept, as operational condition parameters related to the operating conditions of the operational amplifier 100, parameters other than the ambient temperatures Ta1 and Ta2, such as the supply voltage VCC, the reference voltage VSS, the internal temperature Tj (junction temperature), and the load current Iload of the operational amplifier100. The reference voltage VSS may correspond to the ground voltage GND.

Here, when the ambient temperature Ta2 is input via the input node 14, the characteristics setting block 13 prioritizes the ambient temperature Ta2 that is set specifically for the macro model 10 over the ambient temperature Ta1 that is set for the entire system of the circuit design simulator and sets, so as to reflect the ambient temperature Ta2, at least one internal parameter among the internal parameters provided in the power supply block 11 and the filter block 12.

The ambient temperature Ta2 may be a fixed value or a variable value (that is, time series data) that conveys temperature information that changes over time.

For example, consider a case where, as the ambient temperature Ta2, time series data is input which reproduces a rise or fall in temperature proportional to the time elapsed in the simulation. In this case, it is possible to easily simulate the change in the circuit characteristics due to the real-time change in temperature. Thus, it is possible to quickly verify whether the change in temperature causes any problem in the circuit operation.

For another example, consider a case where, as the ambient temperature Ta2, time series data is input that conveys temperature information that changes discretely at constant intervals. In this case, it is possible to perform operation verification covering a plurality of temperature conditions in a single simulation run. Thus, it is possible to eliminate a possibility that a system that has passed verification in a simulation fails to pass verification at the stage of test production, and thus to enable smooth and speedy system designing.

How the internal parameters are set in the characteristics setting block 13 will now be described briefly. For example, in the characteristics setting block 13, using previously stored array data, at least one internal parameter among a plurality of internal parameters provided in the power supply block 11 and the filter block 12 may be set such that the characteristics of the operational amplifier 100 on the circuit design simulator reflect the ambient temperature Ta1 or Ta2 (or other operational condition parameters).

Here, it is preferable that the previously stored array data in the characteristics setting block 13 be derived from evaluation measurement data obtained through actual measurement using the real operational amplifier 100. The evaluation measurement data can be obtained, for example, by creating a plurality of Bode plots (see FIG. 3) while changing the operation conditions of the operational amplifier 100 and finding from the plots the DC gain, the band width, and the like of the operational amplifier 100 that vary with varying operation conditions. Then, based on the evaluation measurement data, the set values of the internal parameters (output voltage value V, resistance value R, and capacitance value C) to be set in each of the power supply block 11 and the filter block 12 can be derived, and these set values can be stored as the array data.

For the array data described above, it is preferable to use a one- or multi-dimensional lookup table in which at least one operation condition parameter is associated with at least one internal parameter. For example, a two-dimensional lookup table may be used in which two operation condition parameters (power supply range VCC-VSS and ambient temperature Ta1 or Ta2) are associated with three internal parameters (output voltage value V, resistance value R, and capacitance value C).

### A Macro Model (Second Embodiment)>

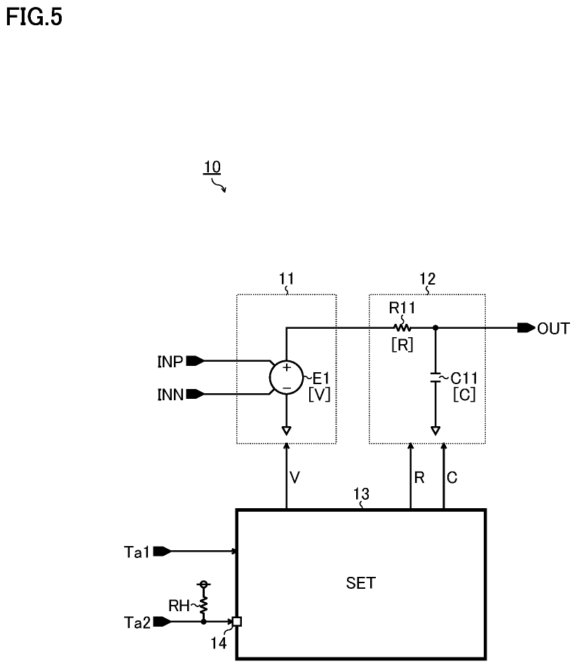

FIG. 5 is a diagram showing a macro model according to a second embodiment simulating the operational amplifier 100. The macro model 10 of this embodiment is based on the first embodiment (FIG. 4) described previously and further includes a pull-up resistor RH.

In the macro model 10 of this embodiment is, the input node 14 is fed with the ambient temperature Ta2 (corresponding to the second temperature condition) as a voltage signal. In this case, for example, the voltage value [V] of the voltage signal fed to the input node 14 can be read as the temperature value [° C.] of the ambient temperature Ta2 as necessary.

The input node 14 is pulled up to a predetermined high voltage terminal (for example, 500 V) via the resistor RH. Thus, when the input node 14 is not fed with the voltage signal, the input node 14 is fixed at a high potential.

Here, when the input node 14 is fed with a voltage signal higher than a predetermined threshold value (for example, 450 V), the characteristics setting block 13 judges that the input node 14 is not fed with the ambient temperature Ta2 and sets the internal parameters of the power supply block 11 and the filter block 12 so as to reflect the ambient temperature Ta1 that is set for the entire system of the circuit design simulator.

By contrast, when the input node 14 is fed with a voltage signal lower than the predetermined threshold value, the characteristics setting block 13 judges that the input node 14 is fed with the ambient temperature Ta2 and sets the internal parameters of the power supply block 11 and the filter block 12 so as to reflect the ambient temperature Ta2 that is set specifically for the macro model 10.

While this embodiment deals with an example where the input node 14 is pulled up, the input node 14 may instead be pulled down.

Although the above embodiments deals with examples of macro models 10 simulating an operational amplifier 100, the configurations of the operational amplifier 100 and the macro models 10 there are all merely examples. Needless to say, the above embodiments can be applied also to any macro models simulating semiconductor integrated circuit devices other than an operational amplifier.

### Examples of Application of the Temperature Profile

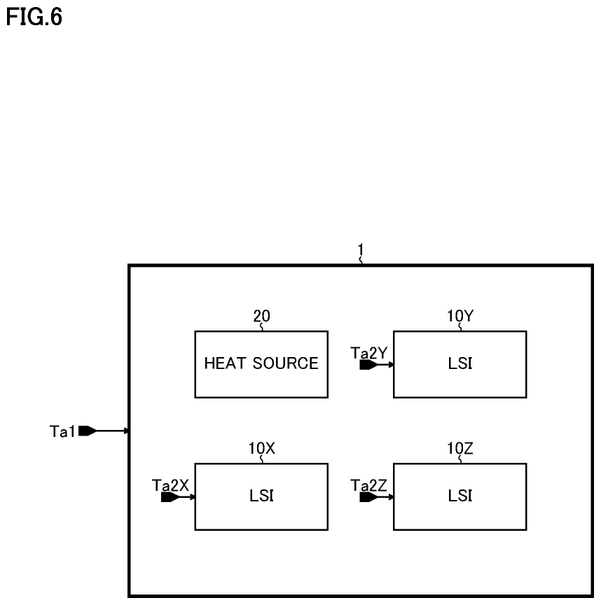

FIG. 6 is a diagram showing an example of application of a temperature profile on a circuit board. In this diagram, three macro models 10X to 10Z are provided to simulate three semiconductor integrated circuit devices mounted at different locations on the circuit board 1. On the circuit board 1, one heat source model 20 is arranged.

The macro models 10X to 10Z are fed with, in addition to an ambient temperature Ta1 (corresponding to a first temperature condition) set in the circuit design simulator, an ambient temperatures Ta2X to Ta2Z (corresponding to a second temperature condition) specific for the macro models 10X to 10Z.

In this way, using macro models 10X to 10Z that allow setting of specific temperature conditions makes it possible, when simulating an entire system with multiple LSI products mounted in it, to perform a simulation that reflects the temperature profile on the circuit board 1 (for example, a temperature distribution where, for example, the closer to the heat source model 20, the higher the ambient temperature and, reversely, the farther from the heat source model 20, the lower the ambient temperature).

For example, by previously acquiring, using a three-dimensional thermal-fluid analysis simulator, temperature data (time series data) at various locations on the circuit board 1 and feeding the temperature data into the macro models 10X to 10Z as the ambient temperatures Ta2X to Ta2Z, it is possible to obtain simulation results consistent with the real device.

### <Circuit Design Simulator>

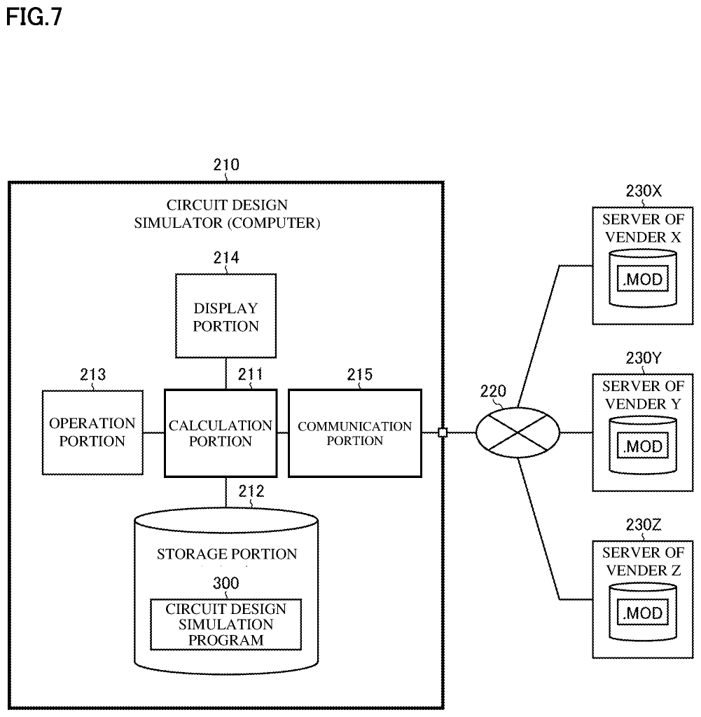

FIG. 7 is a block diagram showing one configuration example of a circuit design simulator that employs the macro model 10 described previously. The circuit design simulator 210 of this configuration example is a computer including a calculation portion 211, a storage portion 212, an operation portion 213, a display portion 214, and a communication portion 215, and is implemented by the calculation portion 211 executing a circuit design simulation program 300 stored in the storage portion 212.

The calculation portion 211 comprehensively controls the operation of the circuit design simulator 210. For example, the calculation portion 211 executes the circuit design simulation program 300 stored in the storage portion 212 and performs various arithmetic operations to make the computer function as the circuit design simulator 210. The calculation portion 211 also recognizes user operations on the operation portion 213, controls display of different screens on the display portion 214, etc. For the calculation portion 211, for example, a CPU (central processing unit) can be used.

The storage portion 212 is used as a storage area for an OS (operation system) program and various software programs (including the circuit design simulation program 300) and also as a storage area for different kinds of data created by a user and as a working area for various software programs. For the storage portion 212, a hard disc drive, a solid state drive, a USB (universal serial bus) memory, and the like can be used.

The operation portion 213 accepts various user operations (a circuit creation operation, a component reference operation, a probe installation operation, etc.) and transmits them to the calculation portion 211. For the operation portion 213, a keyboard, a mouse, a trackball, a pen tablet, a touch panel, and the like can be used.

The display portion 214 displays various screens (a circuit creation field, a component pallet, a waveform drawing window, etc.) based on instructions from the calculation portion 211. For the display portion 214, a liquid crystal display and the like can be used.

The communication portion 215 communicates information via a telecommunication line 220 (the Internet, a LAN (local area network), etc.) based on instructions from the calculation portion 211. For example, the communication portion 15 communicates information via the telecommunication line 220 with servers 230X to 230Z at vendors manufacturing and distributing semiconductor integrated circuit devices, to download macro model files (*.mod) and the like.

By using such a circuit design simulator 210, it is possible to perform simulation verification (characteristics evaluation, operation checking, etc.) with an analog circuit before it is actually test-produced.

### <Circuit Design Simulation Program>

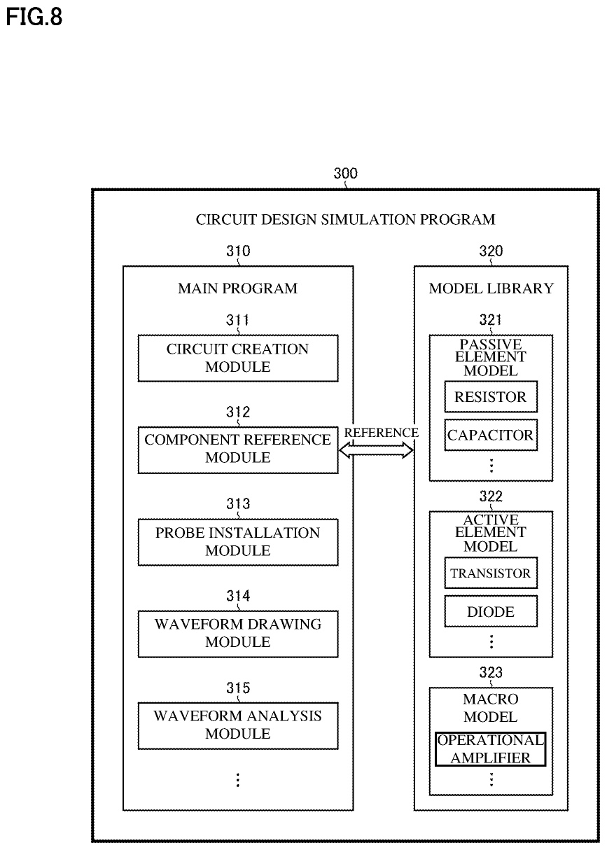

FIG. 8 is a diagram showing one configuration example of the circuit design simulation program 300. The circuit design simulation program 300 (for example, a SPICE circuit design simulation program) is a software program that is executed by a computer to make the computer function as the circuit design simulator 210 (see FIG. 7). The circuit design simulation program 300 of this configuration example includes a main program 310 and a model library 320. The circuit design simulation program 300 is transferred or distributed via a physical media such as an optical disc (a CD-ROM, a DVD-ROM, etc.) or a semiconductor memory (a USB memory, etc.) or via a telecommunication line such as the Internet.

The main program 310 is the base for making the computer function as the circuit design simulator 210 and is formed as a combination of different module programs (for example, a circuit creation module 311, a component reference module 312, a probe installation module 313, a waveform drawing module 314, and a waveform analysis module 315).

The circuit creation module 311 is an element program for making the calculation portion 211 and the display portion 214 create a circuit on the circuit design simulator 210 based on input on the operation portion 213. Using the operation portion 213, a user can arrange, in the circuit creation field, component symbols (resistor, capacitor, transistor, diode, operational amplifier, voltage source, current source, wiring, etc.) displayed on the display portion 214; this leads the circuit creation module 311 to create text-based code in accordance with the arrangement. In this way, a user can create any analog circuit intuitively without directly editing text-based code.

The component reference module 312 is an element program for making the calculation portion 211 and the display portion 214 refer to the model library 320 based on input on the operation portion 213. For example, using the operation portion 213, a user can select the symbol for the operational amplifier from the component pallet displayed on the display portion 214; this leads the component reference module 312 to refer to a macro model 323 of the operational amplifier (corresponding to the macro model 10 described previously) in the model library 320.

The probe installation module 313 is an element program for making the calculation portion 211 and the display portion 214 install a probe (point for measurement of a voltage or current) on the circuit diagram based on input on the operation portion 213. For example, using the operation portion 213, a user can click with a mouse a specific node on the circuit diagram displayed on the display portion 214; this leads the probe installation module 313 to install a probe at the clicked node.

The waveform drawing module 314 is an element program for making the calculation portion 211 and the display portion 214 draw, based on input on the operation portion 213, the waveform at the node at which the probe is installed. For example, when a user using the operation portion 213 installs a probe at the output terminal of the operational amplifier displayed on the display portion 214, the waveform drawing module 314 displays the output waveform (simulated oscilloscope waveform) of the operational amplifier in the waveform drawing window.

The waveform analysis module 315 is an element program for making the calculation portion 211 and the display portion 214 analyze, based on input on the operation portion 213, the waveform at the node at which the probe is installed. Examples of waveform analysis that can be performed in the waveform analysis module 315 include transition analysis, direct-current analysis, small-signal alternating-current analysis, noise analysis, and the like.

The model library 320 includes various simulation models (a passive device model 321, an active device model 322, the macro model 323, etc.) used on the circuit design simulator 210 and is referred to, as a component of the circuit design simulation program 300, by the main program 310 (in particular, by the component reference module 312). The passive device model 321 is a program for making the computer simulate the response of a passive device (resistor, capacitor, etc.) on the circuit design simulator 210. The active device model 322 is a program for making the computer simulate the response of an active device (transistor, diode, etc.) on the circuit design simulator 210. The macro model 323 of the operational amplifier (corresponding to the macro model 10 described previously) is a program for making the computer simulate a response of the operational amplifier on the circuit design simulator 210. Some of the simulation models (the passive device model 321, the active device model 322, and the macro model 323) described above can be downloaded for free via the telecommunication line 220 from the servers 230X to 230Z at vendors manufacturing and distributing semiconductor integrated circuit devices.

By using such a circuit design simulation program 300, it is possible to use a general-purpose computer (personal computer, work station, etc.) as the circuit design simulator 210.

### Overview

To follow is an overview of the various embodiments described above.

For example, according to one aspect of what is disclosed herein, a macro model of a semiconductor integrated circuit device includes: an input node configured to accept input of a second temperature condition which is set specifically and separately from a first temperature condition which is set for the entire system of a circuit design simulator; a functional block configured to approximately or equivalently represent characteristics of the semiconductor integrated circuit device on the circuit design simulator; and a characteristics setting block configured to set an internal parameter of the functional block so as to reflect the second temperature condition when the input node is fed with the second temperature condition. (A first configuration.)

In the macro model according to the first configuration described above, preferably, the characteristics setting block is configured to accept, as the second temperature condition, input of time series data that conveys temperature information that changes over time. (A second configuration.)

In the macro model according to the first or second configuration described above, preferably, the characteristics setting block is configured to set an internal parameter of the functional block so as to reflect the first temperature condition when the characteristics setting block is not fed with the second temperature condition. (A third configuration.)

In the macro model according to any of the first to third configurations described above, preferably, the input node is configured to accept input of a voltage signal as the second temperature condition. (A fourth configuration.)

In the macro model according to the fourth configuration described above, preferably, the input node is configured to be pulled up or pulled down when the input node is not fed with the second temperature condition. (A fifth configuration.)

In the macro model according to any of the first to fifth configurations described above, preferably, the semiconductor integrated circuit device is an operational amplifier. (A sixth configuration.)

In the macro model according to the sixth configuration described above, preferably, the functional block is either a power supply block that represents the DC gain of the operational amplifier or a filter block that represents the band width of the operational amplifier, and the characteristics setting block sets at least one of the output voltage value of the power supply block and the resistance value and the capacitance value of the filter block in accordance with the first temperature condition or the second temperature condition. (A seventh configuration.)

According to another aspect of what is disclosed herein, a circuit design simulation program is executed by a computer including a calculation portion to make the computer function as a circuit design simulator. The program may include at least one macro model according to any of the first to seventh configurations described above and make the computer simulate the response of a semiconductor integrated circuit device on the circuit design simulator. (An eighth configuration.)

The circuit design simulation program according to the eighth configuration described above, preferably, includes, as the at least one macro model, a plurality of macro models configured to simulate a plurality of semiconductor integrated circuit devices mounted at different locations on a circuit board. The plurality of macro models may be each fed with, separately from the first temperature condition set in the circuit design simulator, the second temperature condition, specific for that micro model, that reflects the temperature distribution on the circuit board. (A ninth configuration.)

According to yet another aspect of what is disclosed herein, a circuit design simulator is implemented by a computer executing the circuit design simulation program according to the eighth or ninth configuration described above. (A tenth configuration.)

With the present invention disclosed herein, it is possible to provide a macro model of a semiconductor integrated circuit device that allows free setting of a temperature condition, and to provide a circuit design simulation program and a circuit design simulator that employ such a macro model.

### Further Modifications

The various technical features disclosed herein may be implemented in any other manners than in the embodiments described above, and allow for any modifications made without departure from their technical ingenuity. That is, the above embodiments should be understood to be in every aspect illustrative and not restrictive. The scope of the present invention is defined not by the description of the embodiments given above but by the appended claims, and should be understood to encompass any modifications made in a sense and scope equivalent to those of the claims.

1. A macro model of a semiconductor integrated circuit device for use on a circuit design simulator, comprising:
an input node configured to accept input of a second temperature condition which is set specifically and separately from a first temperature condition which is set for an entire system of the circuit design simulator;
a functional block configured to approximately or equivalently represent characteristics of the semiconductor integrated circuit device on the circuit design simulator; and
a characteristics setting block configured to set an internal parameter of the functional block so as to reflect the second temperature condition when the input node is fed with the second temperature condition.

2. The macro model according to claim 1,
wherein
the characteristics setting block is configured to accept, as the second temperature condition, input of time series data that conveys temperature information that changes over time.

3. The macro model according to claim 1,
wherein
the characteristics setting block is configured to set an internal parameter of the functional block so as to reflect the first temperature condition when the input node is not fed with the second temperature condition.

4. The macro model according to claim 1,
wherein
the input node is configured to accept input of a voltage signal as the second temperature condition.

5. The macro model according to claim 4,
wherein
the input node is configured to be pulled up or pulled down when the input node is not fed with the second temperature condition.

6. The macro model according to claim 1,
wherein
the semiconductor integrated circuit device is an operational amplifier.

7. The macro model according to claim 6,
wherein
the functional block is either
a power supply block that represents a DC gain of the operational amplifier or
a filter block that represents a band width of the operational amplifier, and
the characteristics setting block sets at least one of an output voltage value of the power supply block and a resistance value and a capacitance value of the filter block in accordance with the first temperature condition or the second temperature condition.

8. A circuit design simulation program to be executed by a computer including a calculation portion to make the computer function as a circuit design simulator,
the program including at least one macro model according to claim 1,
the program making the computer simulate a response of a semiconductor integrated circuit device on the circuit design simulator.

9. The circuit design simulation program according to claim 8, the program including, as the at least one macro model, a plurality of macro models configured to simulate a plurality of semiconductor integrated circuit devices mounted at different locations on a circuit board,
wherein
the plurality of macro models are each fed with, separately from the first temperature condition set in the circuit design simulator, the second temperature condition, specific for that micro model, that reflects a temperature distribution on the circuit board.

10. A circuit design simulator that is implemented by a computer executing the circuit design simulation program according to claim 8.
